(19) United States
(12) Patent Application Publication
(10) Pub. No.: US 2026/0233989 A1
(43) Pub. Date: Aug. 13, 2026

(54) Methods of Temperature Sensing in a MEMS Resonator Using Structural Resistance

(71) Applicant: Stathera IP Holdings Inc., Montreal (CA)

(72) Inventors: Riccardo Gatti, Laval (CA); Siddharth Kumanduri, Montreal (CA)

(21) Appl. No.: 19/441,088

(22) Filed: Jan. 6, 2026

Related U.S. Application Data
(60) Provisional application No. 63/756,501, filed on Feb. 10, 2025.

(51) Int. Cl. B81B 7/00; G01K 7/22

(52) U.S. Cl. CPC B81B 7/0087; G01K 7/22; B81B 2201/0271; B81B 2203/0307; B81B 2203/04

(57) ABSTRACT

MEMS devices with co-packaged thermistors are described where a serial path for the thermistor is created through a plurality of thermistor plugs in a cap layer and a plurality of thermistor linkages in a device layer laterally adjacent to a resonator element. In this manner the thermistor resistance can be attributed to resistance of the thermistor plugs and their bonding interfaces, while the more highly doped thermistor linkages in the device layer provide serial connection between the thermistor plugs.

### RELATED APPLICATIONS

This application claims the benefit of priority from U.S. Provisional Patent Application Serial No. 63/756,501 filed on February 10, 2025, the full disclosure of which is incorporated herein by reference.

### BACKGROUND

### Field

Embodiments described herein relate to microelectromechanical systems (MEMS), and more particularly to MEMS resonator structures.

### BACKGROUND INFORMATION

Microelectromechanical systems (MEMS) are small integrated devices or systems that combine electrical and mechanical components. The components can range in size from the sub-micrometer level to the millimeter level, and there can be any number, from one, to a few, to potentially thousands or millions, in a particular system. Some MEMS structures, in particular MEMS resonators, are hermetically sealed within low-pressure cavities to ensure consistent operation in different environments and temperature ranges. The resonance frequency of silicon MEMS resonators depends on temperature. For native silicon the temperature coefficient of frequency (TCF) is approximately 30 ppm/^{o}C. In general, there will be a linear component (TCF1) and a quadratic component (TCF2). One method of passive temperature compensation involves doping the silicon crystal with n- or p-type dopants to reduce TCF2 and altering the resonant mode to minimize TCF1. One can compensate for any residual dependence of frequency on temperature by measuring the local temperature of the MEMS die and compensating for it using a frequency synthesizer such as a (phase-locked loop) PLL frequency synthesizer. One method of measuring the local MEMS temperature is to use a thermistor.

### SUMMARY

MEMS devices with co-packaged thermistors and methods of fabrication are described. In an embodiment, a MEMS device with co-packaged thermistor includes a support layer including a lower cavity, a device layer bonded to the support layer, and a cap layer bonded to the device layer. The device layer includes a resonator element directly over the lower cavity and a plurality of laterally separate thermistor linkages. The cap layer includes a plurality of thermistor plugs bonded to the plurality of laterally separate thermistor linkages. A first contact terminal is in electrical connection with the first thermistor plug, a second contact terminal is in electrical connection with a second thermistor plug of the plurality of thermistor plugs, and a serial path exists from the first contact terminal, through the plurality of thermistor plugs and the plurality of laterally separate thermistor linkages to the second contact terminal for voltage measurement. In this configuration the thermistor resistance can be dominated by resistance of the thermistor plugs and their bonding interfaces, while the more highly doped thermistor linkages in the device layer provide serial connection between the thermistor plugs.

### BRIEF DESCRIPTION OF THE DRAWINGS

FIGS. 1A-1D are composite schematic cross-sectional side view illustrations of MEMS devices with co-packaged thermistors in accordance with embodiments.

FIG. 2 is a schematic top layout view of a MEMS device including a co-packaged thermistor with thermistor linkages located outside of the hermetically sealed cavity in accordance with an embodiment.

FIG. 3 is a schematic top layout view of a MEMS device including a co-packaged thermistor with thermistor linkages located inside the hermetically sealed cavity in accordance with an embodiment.

FIG. 4A is an isometric view illustration of a MEMS device with a rectangular resonator element in accordance with an embodiment.

FIG. 4B is a schematic top layout view of the MEMS device 100 of FIG. 4A with a co-packaged thermistor in accordance with an embodiment.

FIGS. 5A-5B are isometric view illustrations of a MEMS device with a rectangular resonator element in accordance with an embodiment

FIG. 5C is a schematic top layout view of the MEMS device of FIGS. 5A-5B with a co-packaged thermistor in accordance with an embodiment.

FIGS. 6A-6B are isometric view illustrations of a MEMS device with a circular resonator element in accordance with an embodiment

FIG. 6C is a schematic top layout view of the MEMS device of FIGS. 6A-6B with a co-packaged thermistor in accordance with an embodiment.

FIG. 7 is a circuit diagram for a two-terminal co-packaged thermistor in accordance with an embodiment.

FIG. 8 is a circuit diagram for a four-terminal co-packaged thermistor in accordance with an embodiment.

### DETAILED DESCRIPTION

Embodiments describe MEMS devices and methods of fabrication including a co-packaged thermistor formed as a continuous chain of silicon passing through multiple layers of the MEMS device thereby using the temperature-dependent structural and contact resistances of the existing silicon in the MEMS device as a temperature sensor. In particular, a thermistor can be co-packaged with a resonator element to reduce thermal lag between the thermistor and a resonator element. In an embodiment, a MEMS device includes a support layer including a lower cavity, a device layer bonded to the support layer, and a cap layer bonded to the device layer. The device layer may further include a resonator element directly over the lower cavity and a plurality of laterally separate thermistor linkages. The cap layer may further include a plurality of thermistor plugs bonded to the plurality of laterally separate thermistor linkages. In accordance with embodiments, a first contact terminal is in electrical connection with a first thermistor plug, and a second contact terminal in electrical connection with a second thermistor plug, and the thermistor components are fabricated such that a serial path exists from the first contact terminal, through the plurality of thermistor plugs and the plurality of laterally separate thermistor linkages to the second contact terminal. The fabrication sequences described herein may be wafer-scale fabrication sequences in which a plurality of MEMS devices is fabricated and singulated from a processed wafer stack.

In one aspect, it has been observed that the high doping levels required in the device layer to compensate for TCF2 normally precludes the use of a thermistor in the device layer because this can render the thermistor pattern too conductive. In accordance with embodiments, multiple thermistor plugs, or silicon interconnects, in the cap layer formed of lower doped (or undoped) and higher resistivity material (e.g., silicon), as well as additional contact resistance between the thermistor plugs and laterally separate thermistor linkages in the device layer, allows a higher overall resistance to be achieved in a much smaller area than if the thermistor pattern were formed primarily in the device layer. In such a configuration the overall resistance of the thermistor can be dominated by resistance of the thermistor plugs and their bonding interfaces, with the highly doped thermistor linkages in the device layer serving as interconnects between the thermistor plugs rather than a significant source of resistance. This can also mitigate nonlinear contributions to the temperature coefficient of resistivity of the thermistor since overall resistance of the thermistor may be dominated by the cap layer that may have a more linear temperature coefficient of resistivity than a more highly doped device layer.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

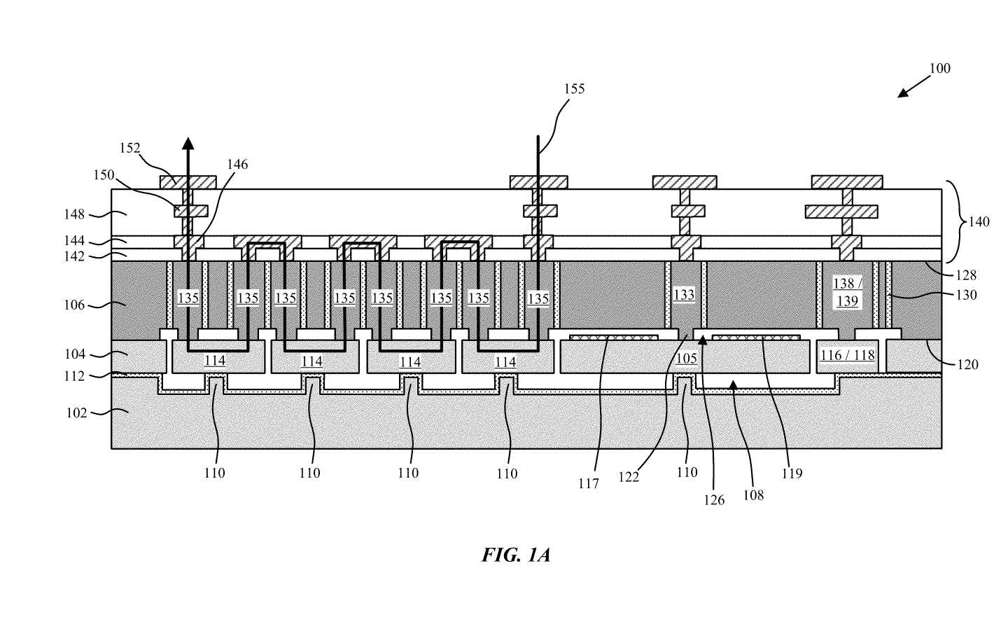

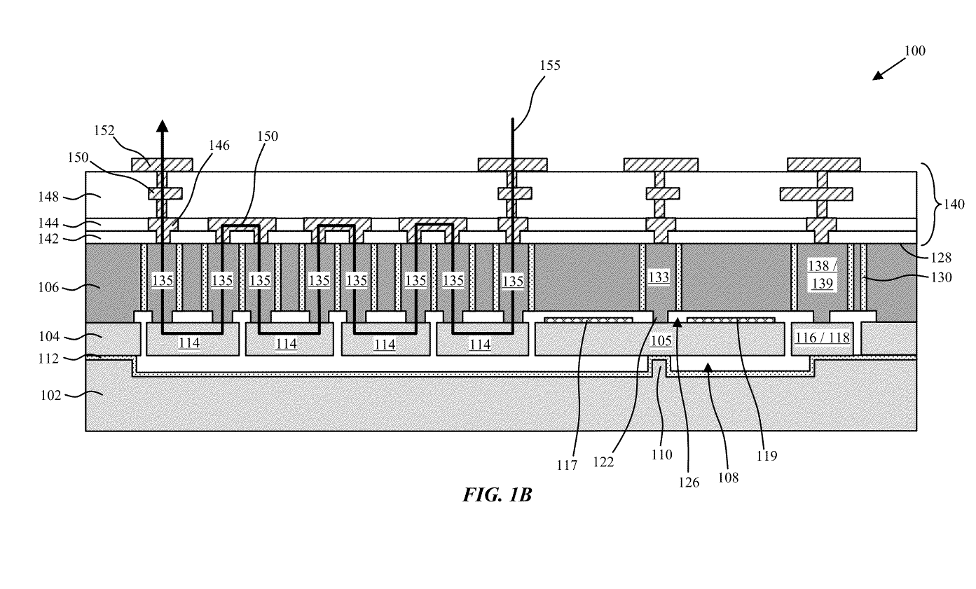

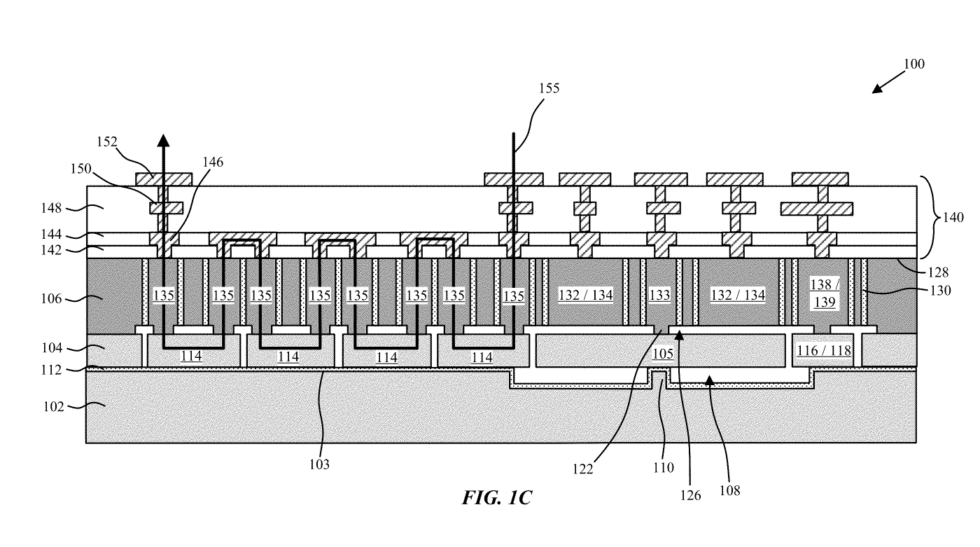

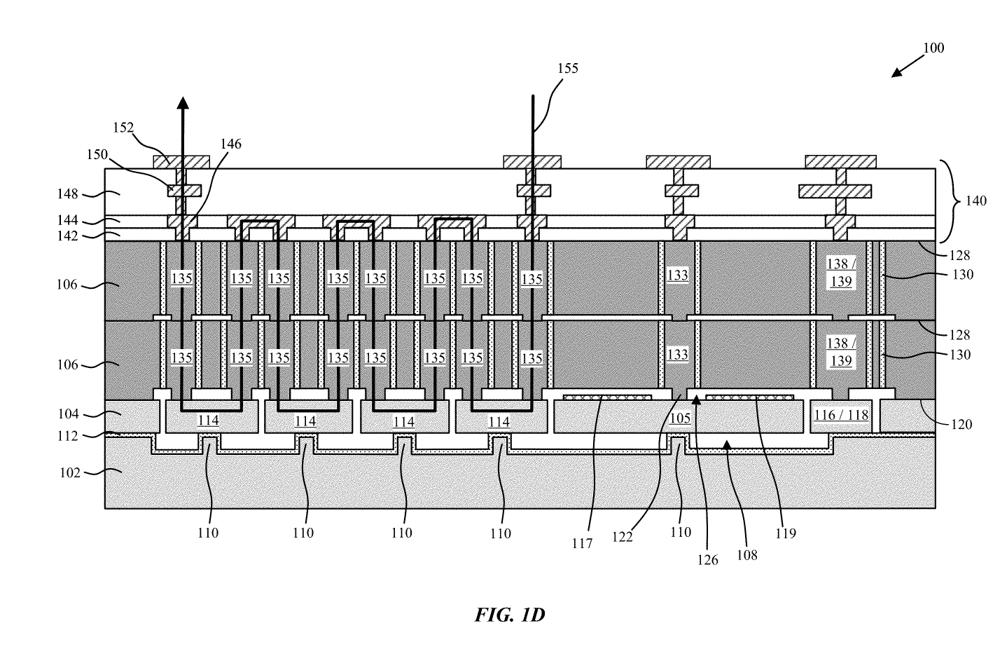

Referring now to FIGS. 1A-1D, composite schematic cross-sectional side view illustrations are provided of MEMS devices with co-packaged thermistors in accordance with embodiments. Generally, the MEMS devices in accordance with embodiments can include resonator elements that are suspended within a hermetically sealed cavity that is maintained at low pressure, and a co-packaged thermistor. It is to be appreciated that the figures are composite schematic cross-sectional side view illustrations that illustrate various features together in the same illustration, while actual arrangements when viewed from above may be different. It is also to be appreciated that the figures are not necessarily drawn to scale, and that the thermistors can be integrated with a variety of MEMS devices, such as any bulk acoustic wave (BAW) or surface acoustic wave (SAW) resonator, etc. The resonators can be capacitively-transduced resonators and/or piezoelectrically-transduced resonators. Different configurations with different electrode arrangements may be implemented without departing from the embodiments.

As shown, the MEMS devices 100 can include a support layer 102, a device layer 104 and cap layer 106. The support layer 102 may be formed of any suitable handle substrate such as glass, silicon, etc. For example, the support layer 102 may be a bulk silicon substrate, or a multiple layer substrate such as silicon on insulator (SOI) substrate. As shown, the support layer 102 can be patterned to include a lower cavity 108, e.g., 5 - 50 µm recess, and optionally one or more anchors 110. An insulator layer 112, such as silicon oxide, may be formed (including grown or deposited) over the top side (top surface) of the support layer 102 to provide electrical insulation from subsequently bonded layers. A device layer 104 may then be bonded to the support layer 102, for example with fusion bonding a silicon-silicon oxide interface. The device layer 104 may also be a silicon substrate, which may be pre-processed to include various MEMS structures or processed after wafer bonding. Exemplary MEMS structures include resonators, temperature sensors (thermistors), humidity sensors, gas sensors, accelerometers, etc. In accordance with embodiments, the device layer 104 can additionally include a plurality of laterally separate thermistor linkages 114.

In the particular embodiment illustrated in FIG. 1A each individual thermistor linkage 114 can optionally be supported by a corresponding anchor 110. Alternatively, the laterally separate thermistor linkages 114 can be suspended over the cavity 108 without lower support as shown in FIG. 1B, or be supported by a continuous and flat top surface 103 of the support layer 102 as shown in FIG. 1C. In some embodiments multiple cap layers 106 can be included, for example as illustrated in FIG. 1D in order to increase the serial path length through the thermistor plugs.

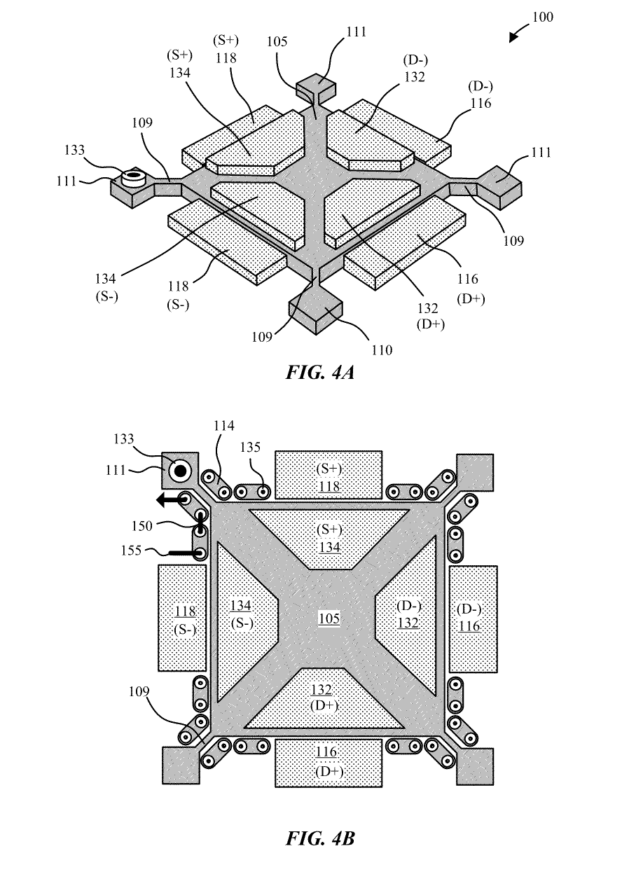

The device layer in accordance with embodiments may be homogenously doped with a dopant concentration on an order of 10¹⁹ cm⁻³ and higher, for example, to compensate for TCF2. In the particular embodiments illustrated in FIGS. 1A-1D the device layer 104 may be approximately 5 – 100 µm thick, and is patterned to include a resonator element 105 that is supported by at least one anchor 110, and a plurality separate thermistor linkages 114. The thermistor linkages 114 may each optionally be supported by corresponding anchors 110, be suspended over the cavity 108 without lower support, or be supported by a continuous top surface 103 of the support layer 102. The device layer 104 may include additional structures, such as in-plane drive electrodes 116 and in-plane sense electrodes 118, for example. While a single in-plane drive electrode 116 or in-plane sense electrode 118 is illustrated, it is understood that one or more of the in-plane drive electrodes 116 and in-plane sense electrodes 118 may be arranged laterally adjacent to the resonator element 105. Additionally, while the resonator element 105 is illustrated as being vertically supported by one or more anchors 110, the device layer 104 can alternatively include one or more tethers connected to the resonator element 105 and/or one or more side anchors (e.g., see FIGS. 4A-4B) to laterally support the resonator element 105 and suspend the resonator element within the upper and lower cavities.

A cap layer 106 (e.g., patterned silicon wafer) can be bonded to (e.g., directly to) the device layer 104, such as with fusion bonding to create silicon-silicon bonds, or alternatively with metal-metal bonding such as with eutectic bonding. As shown, a patterned contour can be formed in the bottom side 120 (bottom surface) of the cap layer 106 to include a plurality anchors 122, which may be in the shape of mesas with faceted/sloped or straight sidewalls. Anchors 122 can be bonded to various MEMS structures within the device layer 104, such as thermistor linkages 114, and optionally the resonator element 105, in-plane drive electrodes 116 and in-plane sense electrodes 118, side anchors 111, etc. In an exemplary embodiment illustrated in FIG. 1C, patterned areas between the anchors 122 can be positioned over the resonator element 105 to define area for capacitive out-of-plane drive electrodes 132 and/or out-of-plane sense electrodes 134. The space between the bottom surface of the cap layer 106 and device layer 104 can form an upper cavity 126, where the resonator element 105 is hermetically sealed in the cavity volume defined by the upper cavity 126 and lower cavity 108. The height of the upper cavity 126 can optionally define an out-of-plane transduction gap when capacitive out-of-plane drive electrodes 132 and/or out-of-plane sense electrodes 134 are included.

Both in-plane and out-of-plane resonance may also be achieved using piezoelectric transduction as shown in FIGS. 1A-1B where piezoelectric drive electrodes 117 and piezoelectric sense elections 119 can be formed of stacked piezoelectric layers and metal layers on the resonator element 105 and connected to via plugs in the cap layer and corresponding electrical contact terminals, for example with metal wiring spanning over tethers connected to the resonator element.

Still referring to FIGS. 1A-1D, a plurality of isolation trenches 130 can also be formed in the bottom side 120 of the cap layer 106 and extend completely through a thickness of the cap layer to a top side 128 of the cap layer. Each isolation trench 130 may be partially or completely filled with a liner layer, such as silicon oxide, and may optionally be filled with a filler material, which can be anything conformal such as polysilicon, tetraethyl orthosilicate (TEOS)-oxide grown film, etc. During fabrication, the isolation trenches 130 may have been formed in the cap layer 106 prior to being bonded to the device layer, followed by a grinding (and polishing) operation to reduce a thickness of the cap layer 106 and reveal the isolation trenches 130. The reveal operation of the isolation trenches 130 can also be considered a via (plug) reveal operation where vias (e.g., silicon vias/plugs or electrodes) are defined by a contour of laterally surrounding isolation trenches 130. In accordance with embodiments, the grinding operation creates a planarized surface formed of (and spanning) the top side 128 of the cap layer 106 and the top sides of the isolation trenches 130. Various structures may be defined by the isolation trenches 130, such as thermistor plugs 135 for electrical connection with the thermistor linkages 114 in the device layer, resonator plug 133 optionally provide mechanical support for the resonator and/or provide a bias voltage to the resonator element 105, drive electrode plug(s) 138 and sense electrode plug(s) 139 to transfer a voltage to in-plane drive electrode(s) 116 and in-plane sense electrode(s) 118, as well as optional out-of-plane drive electrode(s) 132 and out-of-plane sense electrode(s) 134. Drive electrode plug(s) and sense electrode plug(s) can also be connected to the piezoelectric drive electrode(s) 117 and piezoelectric sense electrode(s) 119 (e.g., to a metal wiring layer spanning over tethers and side anchors) for in-plane and/or out-of-plane resonance.

At this stage BEOL processing can be formed over the planarized surface to provide electrical routing, passivation, and optionally the formation of a hydrogen barrier layer. Further processing may then be formed, such as bonding to an integrated circuit wafer and/or singulation of multiple MEMS devices from the stacked wafer structure.

As shown, the BEOL build-up structure 140 may include one or more passivation layers 142, 144. In an embodiment the first passivation layer 142 is a single layer or multiple layer stack that may be formed of one or more materials to mitigate small molecule diffusion, such as hydrogen, helium, etc. into the cavity volume. Exemplary materials include insulating materials such as silicon nitride, aluminum nitride, aluminum oxide, or silicon carbide to prevent shorting across the top surface of the cap layer 106. Additional layers can also be included such as aluminum, copper, titanium, nickel, gold, chromium, molybdenum, titanium nitride, metal silicide, polysilicon, etc. to assist in blocking diffusion. The top passivation layer 144 may be formed a suitable dielectric material such as silicon oxide used for BEOL structures to provide electrical insulation, film quality, and deposition rate. In particular, when the passivation layer 142 is formed of a high-stress nitride that cannot be deposited thick enough to provide sufficient dielectric insulation of metal traces, adding the optional top passivation layer 144 can provide improved dielectric insulation.

Openings may then be formed through the one or more passivation layers 142, 144 to expose the various MEMS components and/or connections followed by deposition of electrical contact terminals 146. For example, the electrical contact terminals 146 can be formed on the thermistor plug 135 inputs, one or more out-of-plane via drive electrodes 132, anchor 122, one or more out-of-plane via sense electrodes 134, and thermistor plug 135 output, etc. Electrical contact terminals 146 can additionally be formed on one or more drive electrode plugs 138 and one or more sense electrode plugs 139 for in-plane driving and sensing.

The electrical contact terminals 146 may be formed of one or more layers including various metal layers and alloys thereof, polysilicon, etc. Selection of materials may additionally depend upon the doping concentration of the cap layer. A variety of arrangements are possible including metal layers such as copper, gold etc., polysilicon, and multi-layer combinations thereof.

Additional BEOL processing can be performed following the formation of the electrical contact terminals 146, such as the formation additional dielectric layer 148 and wiring layers 150 connected to chip contact pads 152.

In an embodiment, MEMS device 100 with co-packaged thermistor includes a support layer 102 including a lower cavity 108, and a device layer 104 bonded to the support layer, the device layer including a resonator element 105 directly over the lower cavity 108 and a plurality of laterally separate thermistor linkages 114. A cap layer may be bonded to the device layer 104, the cap layer including a plurality of thermistor plugs 135 bonded to the plurality of laterally separate thermistor linkages 114. In accordance with embodiments, a first contact terminal 146 is in electrical connection with a first thermistor plug 135, and a second contact terminal 146 is in electrical connection with a second thermistor plug, and a serial path 155 exists from the first contact terminal 146, through the plurality of thermistor plugs 135 and the plurality of laterally separate thermistor linkages 114 to the second contact terminal 146.

In some embodiments, the serial path 155 passes through multiple metal layers 150 and via connections therebetween. In the particular embodiments illustrated the serial path 155 may pass through a lower metallization layer 150, which may be the same layer or different layer used to form the contact terminals 146. More particularly, the path between internal thermistor plugs 135, as opposed to the terminal or end thermistor plugs 135 in the serial path 155, may be confined to lower metallization layer(s) and be buried within the BEOL build-up structure 140, and underneath higher metallization layer(s) and chip contact pads 152.

In some embodiments the device layer 104 further includes an in-plane capacitive drive electrode 116 laterally adjacent to the resonator element 105, and the cap layer includes a drive electrode plug 138 bonded to the in-plane capacitive drive electrode 116, for example with fusion bonding or eutectic bonding. In accordance with embodiments, resistance of the serial path 155 can be largely controlled by number and size of the thermistor plugs 135 in the cap layer 106, doping concentration of the cap layer, and contact resistance of bonding interfaces of the thermistor plugs. One manner for increasing resistance is to decrease area and volume of the thermistor plugs 135. For example, the thermistor plugs 135 can each have a smaller lateral area and volume than the drive electrode plug(s) 138. The thermistor plugs 135 may be designed with a smaller lateral area and volume that other features within the cap layer 106, such as resonator plug 133, sense electrode plug(s) 139, out-of-plane drive electrode(s) 132, out-of-plane sense electrode(s) 134, etc. The cap layer 106 may be undoped, or may be doped, for example with a dopant concentration that is less than or equal to a dopant concentration of the device layer 104, which may be homogenously doped with a dopant concentration on an order of 10¹⁹ cm⁻³ and higher, for example. Referring now to FIG. 1D, in some embodiments multiple cap layers 106 can be included to increase total resistance of the serial path 155. The multiple cap layers 106 may have the same or different doping profiles, and may be bonded to one another using similar methods such as fusion bonding or eutectic bonding. In an embodiment, the MEMS device includes a second cap layer on the first cap layer, the second cap layer including a second plurality of second thermistor plugs bonded the plurality of thermistor plugs in the first cap layer.

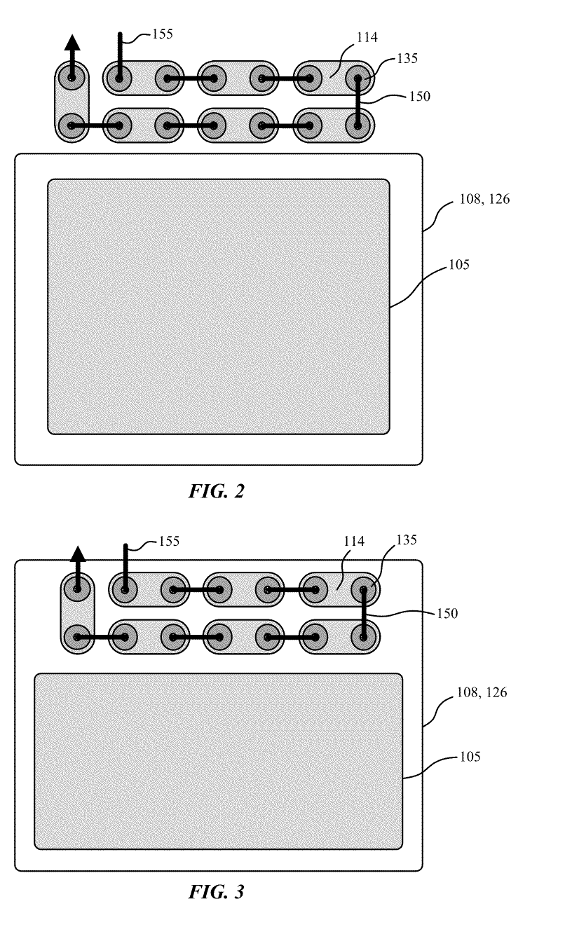

Up until this point composite schematic cross-sectional side view illustrations have been discussed with the understanding that the various components illustrated together may have different orientations when viewed from above. For example, the thermistor linkages 114 may be contained inside the hermetically sealed cavity structure, or outside of the hermetically sealed cavity structure. FIG. 2 is a schematic top layout view of a MEMS device including a co-packaged thermistor with thermistor linkages 114 located outside of the hermetically sealed cavity. FIG. 3 is a schematic top layout view of a MEMS device including a co-packaged thermistor with thermistor linkages 114 located inside the hermetically sealed cavity. As shown in each illustration, a resonator element 105 may be within the perimeters of the lower cavity 108 and upper cavity 126. The plurality of separate thermistor linkages 114 in the device layer 104 may be positioned laterally outside of the lower cavity 108 and/or underneath the upper cavity 126 as shown in FIG. 2, or above the lower cavity 108 and/or underneath the upper cavity 126 as shown in FIG. 3. A variety of orientations are possible, inclusive of differently sized lower and upper cavities. Thus, embodiments are not limited to the two general configurations illustrated in FIGS. 2-3.

It is also to be appreciated that all figures provided are not necessarily drawn to scale, and that the thermistors can be integrated with a variety of MEMS devices, such as any bulk acoustic wave (BAW) or surface acoustic wave (SAW) resonator, etc. The resonators can be capacitively-transduced resonators and/or piezoelectrically-transduced resonators. Different configurations with different electrode arrangements may be implemented without departing from the embodiments.

Referring now to FIG. 4A, an isometric view illustration is provided of a MEMS device 100 with rectangular resonator element 105 in accordance with an embodiment. As depicted, the square resonator element 105 may be part of a capacitively-transduced Lamé mode resonator including a pair of in-plane drive electrodes 116 denoted by D+/D− and a pair of in-plane sense electrodes 118 denoted by S+/S−, disposed around its periphery whilst the resonator element 105 itself is direct current (DC) biased through a resonator plug 133 at one or more side anchors 111. In this instance the side anchors 111 are connected to corners of the resonator element 105 with tethers 109 and are coupled to an electrical contact terminal through a resonator plug 133.

In operation, the two in-plane drive electrodes 116 are used to provide two drive signals that are 180° out of phase, as denoted D+/D−. Another set of in-plane sense electrodes 118, denoted S+/S−, are used to collect the two out of phase output signals and recombine them. A bias voltage can additionally be provided to the resonator element 105 through a resonator plug 133. Typically, this would be used for frequency tuning.

The MEMS device 100 in accordance with embodiments may additionally include out-of-plane via drive electrodes 132 and out-of-plane via sense electrodes 134. For example, the out-of-plane via drive electrodes 132 and out-of-plane via sense electrodes 134 can be positioned over a top surface of the resonator element 105 and separated by a gap distance (such as 0.05 – 2.0 microns) for capacitive transduction of the resonator element 105. Similar to the in-plane drive electrodes 116 and in-plane sense electrodes 118, the out-of-plane via drive electrodes 132 and out-of-plane via sense electrodes 134 can be utilized to drive and collect out of phase signals and recombine them. The resonator element 105 may further be configured such that the in-plane drive electrodes 116 excites an in-plane resonance mode, and the out-of-plane via electrodes 132 excites an out-of-plane resonance mode in a controlled manner. Herein, “a controlled manner” refers to selectively exciting one, both or neither of the in-plane and out-of-plane resonance mode. For an in-plane resonance mode, the resonator element may be deflectable in plane into open space laterally around the resonator element. For an out-of-plane resonance mode the resonator element may be deflectable into the lower cavity and upper cavity.

FIG. 4B is a schematic top layout view of the MEMS device 100 of FIG. 4A with a co-packaged thermistor in accordance with an embodiment. As shown, the plurality of thermistor linkages 114 may be located laterally adjacent to the resonator element 105.

It is to be appreciated that while the out-of-plane via drive electrodes 132 and out-of-plane via sense electrodes 134 are described and illustrated as being part of the cap layer, and being used for capacitive transduction, that the arrangements shown in FIGS. 4A-4B can also be achieved with piezoelectric drive electrodes 117 and piezoelectric sense electrodes 119 deposited onto the resonator element 105 for in-plane and/or out-of-plane resonance (e.g., as similarly illustrated for the out-of-plane via drive electrodes 132 and out-of-plane via sense electrodes 134 over the resonator element 105).

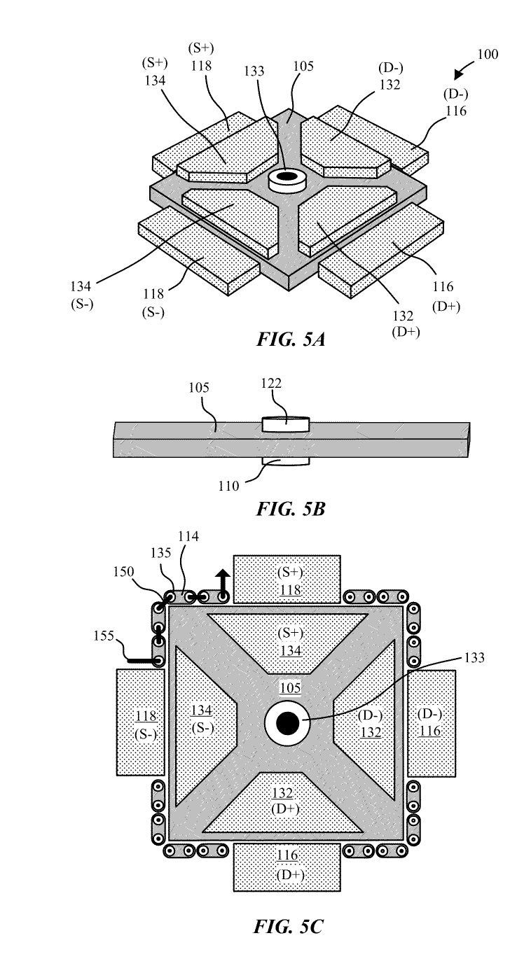

Rather than tethering the resonator element 105 to side anchors 111, the resonator element 105 can be supported by centrally located anchors. FIGS. 5A-5B are isometric view illustrations of a MEMS device with rectangular resonator element 105 in accordance with an embodiment. In interest of clarity the various sense and drive electrodes are not illustrated in FIG. 5B. As shown, the resonator element 105 can be supported by one or more anchors 110, 122 on a bottom and/or top side of the resonator element 105. Similar to the capacitively-transduced resonator depicted in FIG. 4A, the capacitively-transduced resonator depicted in FIG. 5A includes a pair of in-plane drive electrodes 116 denoted by D+/D− and a pair of in-plane sense electrodes 118 denoted by S+/S− disposed around its periphery whilst the resonator element 105 itself is DC biased through one or more anchors 122. The one or more anchors 122 may be physically connected with the resonator element 105 to provide physical support, and optionally function as a DC bias electrode. The one or more anchors 122 may also be physically connected with the resonator element 105 to provide physical support. Similar to FIG. 4A, out-of-plane via drive electrodes 132 and out-of-plane via sense electrodes 134 may optionally be included above the resonator element 105 for out-of-plane driving and sensing.

FIG. 5C is a schematic top layout view of the MEMS device 100 of FIGS. 5A-5B with a co-packaged thermistor in accordance with an embodiment. As shown, the plurality of thermistor linkages 114 may be located laterally adjacent to the resonator element 105.

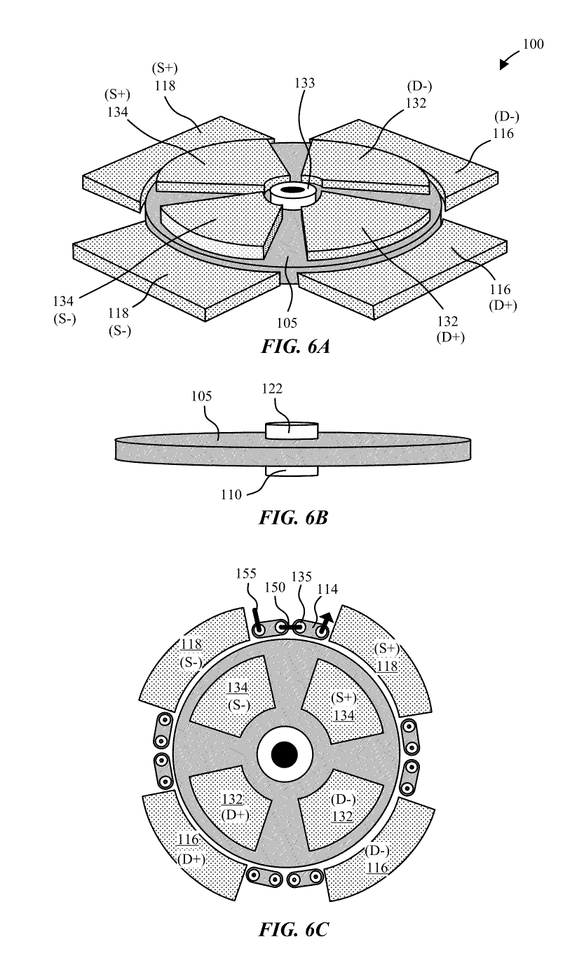

FIGS. 6A-6B are isometric view illustrations of a MEMS device circular resonator element 105 in accordance with an embodiment. In interest of clarity the various sense and drive electrodes are not illustrated in FIG. 6B. FIG. 6C is a schematic top layout view of the MEMS device 100 of FIGS. 6A-6B with a co-packaged thermistor in accordance with an embodiment. FIGS. 6A-6C are substantially similar to those of FIGS. 5A-5C, with only differences in shape/size of the features.

Up until this point exemplary MEMS devices have been described in which a thermistor is co-packaged with a resonator element with continuous resonating region that can optionally be transduced by multiple transducers. In accordance with embodiments, the thermistors can also be co-packaged with a resonator elements include distinct resonating regions that can be independently transduced.

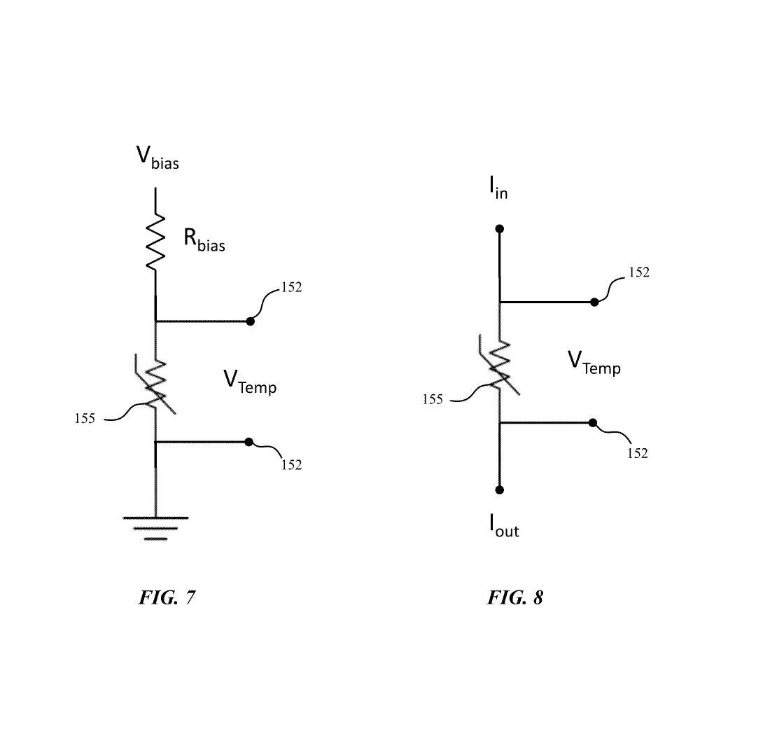

Referring now to FIG. 7 and FIG. 8 circuit diagrams are provided for two-terminal and four-terminal co-packaged thermistors, respectively. In each embodiment, the terminals are made with reference to connections made to chip contact pads 152 connected to the serial path 155. Both circuit diagrams operate in accordance with a similar basic principle in that that voltage can be measured across opposite ends of the serial path 155 at the chip contact pads 152.

In order to measure voltage across the serial path 155, a reference voltage or current is supplied. In one embodiment, a reference voltage is supplied by a chip contact pad that is DC biased. In one implementation the reference voltage bias (Vbias), resistance bias (Rbias), ground, and voltage differential measurement (Vtemp) are all provided in a controller, such as an application specific integrated circuit (ASIC) or system on chip die. The reference voltage bias can also be shared within the MEMS structure. For example, the chip contact pad 152 coupled with resonator plug 135 can also provide a reference voltage for the thermistor. In an exemplary two-terminal configuration a voltage source is coupled with a first thermistor plug 135 of the plurality of thermistor plugs, and an electrical ground is coupled with a second thermistor plug 135 of the plurality of thermistor plugs, where the serial path exists through the first thermistor plug to the second thermistor plug.

In an exemplary four-terminal configuration separate current inputs and outputs are provided to the serial path 155. For example, a current input (which may also be connected is its own chip contact pad) is coupled with a first thermistor plug 135 of the plurality of thermistor plugs, and a current output (which may also be connected to its own chip contact pad) is coupled with a second thermistor plug 135 of the plurality of thermistor plugs, where the serial path exists through the first thermistor plug to the second thermistor plug.

In utilizing the various aspects of the embodiments, it would become apparent to one skilled in the art that combinations or variations of the above embodiments are possible for forming a MEMS resonator with co-packaged thermistor. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration. Furthermore, it is to be appreciated that the figures have been provided for illustrational purposes and may not be to scale. Also, in the interest of conciseness and reducing the total numbers of figures, a given figure may be used to illustrate the features of more than one aspect of the disclosure, and not all elements in the figure may be required for a given aspect.

What is claimed is:

1. A MEMS device with co-packaged thermistor comprising:
a support layer including a lower cavity;
a device layer bonded to the support layer, the device layer including a resonator element directly over the lower cavity and a plurality of laterally separate thermistor linkages;
a cap layer bonded to the device layer, the cap layer including a plurality of thermistor plugs bonded to the plurality of laterally separate thermistor linkages; and
a first contact terminal in electrical connection with a first thermistor plug of the plurality of thermistor plugs, and a second contact terminal in electrical connection with a second thermistor plug of the plurality of thermistor plugs;
wherein a serial path exists from the first contact terminal, through the plurality of thermistor plugs and the plurality of laterally separate thermistor linkages to the second contact terminal.

2. The MEMS device of claim 1, wherein the support layer includes one or more anchors, and the resonator element is bonded to the one or more anchors.

3. The MEMS device of claim 1, wherein the device layer includes one or more side anchors bonded to the support layer and connected with the resonator element.

4. The MEMS device of claim 3, wherein each side anchor of the one or more side anchors is connected to the resonator element with one or more tethers in the device layer.

5. The MEMS device of claim 1, wherein the device layer further comprises an in-plane capacitive drive electrode laterally adjacent to the resonator element.

6. The MEMS device of claim 5, wherein the cap layer further comprises a drive electrode plug bonded to the in-plane capacitive drive electrode.

7. The MEMS device of claim 6, wherein:
the device layer further comprises an in-plane capacitive sense electrode laterally adjacent to the resonator element; and
the cap layer further comprises a sense electrode plug bonded to the in-plane capacitive sense electrode.

8. The MEMS device of claim 6, wherein each thermistor plug of the plurality of thermistor plugs has a smaller lateral area than the drive electrode plug.

9. The MEMS device of claim 5, wherein the cap layer further comprises an out-of-plane drive electrode directly over the resonator element.

10. The MEMS device of claim 9, wherein the cap layer further comprises an out-of-plane sense electrode directly over the resonator element.

11. The MEMS device of claim 1, wherein the plurality of laterally separate thermistor linkages is directly over the lower cavity.

12. The MEMS device of claim 1, further comprising:
a piezoelectric drive electrode on the resonator element; and
a drive electrode plug in the cap layer;
wherein the piezoelectric drive electrode is electrically connected with the drive electrode plug.

13. The MEMS device of claim 12, further comprising:
a piezoelectric sense electrode on the resonator element; and
a sense electrode plug in the cap layer;
wherein the piezoelectric sense electrode is electrically connected with the sense electrode plug.

14. The MEMS device of claim 1, wherein the device layer is homogenously doped with a dopant concentration on an order of 10¹⁹ cm⁻³ and higher.

15. The MEMS device of claim 1, wherein the cap layer and the device layer are both doped, and the cap layer has a dopant concentration that is less than or equal to a dopant concentration of the device layer.

16. The MEMS device of claim 1, further comprising a second cap layer on the cap layer, the second cap layer including a second plurality of second thermistor plugs bonded the plurality of thermistor plugs in the cap layer.

17. The MEMS device of claim 1, further comprising a current input coupled with a first thermistor plug of the plurality of thermistor plugs, and current output coupled with a second thermistor plug of the plurality of thermistor plugs, wherein the serial path existing through the first thermistor plug to the second thermistor plug.

18. The MEMS device of claim 1, further comprising a voltage source coupled with a first thermistor plug of the plurality of thermistor plugs, and an electrical ground coupled with a second thermistor plug of the plurality of thermistor plugs, wherein the serial path existing through the first thermistor plug to the second thermistor plug.
